(19) United States
(12) Patent Application Publication
(10) Pub. No.: US 2013/0163207 A1
(43) Pub. Date: Jun. 27, 2013

(54) HEAT SINK

(71) Applicants: GUO-YI CHEN, Shenzhen City (CN); LEI LIU, Shenzhen City (CN)

(72) Inventors: GUO-YI CHEN, Shenzhen City (CN); LEI LIU, Shenzhen City (CN)

(73) Assignees: HON HAI PRECISION INDUSTRY CO., LTD., New Taipei (TW); HONG FU JIN PRECISION INDUSTRY (ShenZhen) CO., LTD., Shenzhen City (TW)

(21) Appl. No.: 13/340,717

(22) Filed: Dec. 30, 2011

(30) Foreign Application Priority Data
Dec. 26, 2011 (CN) 201110440370.3

(51) Int. Cl. H05K 7/20

(52) U.S. Cl. 361/720

(57) ABSTRACT

A heat sink for mounting to any circuit board with locating holes is provided. The heat sink includes a main body attached on the circuit board, a number of fixing arms each defining a number of mounting holes, and a number of connecting members allowing a fixing arm to pivot about the connecting member. The fixing arms can make use of locating holes in different locations in different circuit boards for attaching the heat sink to any circuit board.

### BACKGROUND

1. Technical Field

The present disclosure relates to a heat sink.

2. Description of Related Art

Heat sinks are used in electronic devices, such as computers, for dissipating heat from electronic components. A heat sink defines a plurality of mounting holes. The heat sink is secured to a circuit board with a plurality of fasteners, such as screws, extending through the mounting holes of the heat sink, and engaged in corresponding locating holes defined in the circuit board.

Layouts of the locating holes of different circuit boards may vary. However, the shape and fixing dimensions of the heat sink are unchangeable. Therefore, the heat sink can only be applied to circuit boards with a particular layout of locating holes. Thus, the application of the heat sink is not flexible and not general.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a heat sink.

FIG. 2 is assembled, isometric view of the heat sink of FIG. 1 and a first circuit board.

FIG. 3 is a top plan view of FIG. 2.

FIG. 4 is a top plan view showing the heat sink of FIG. 1 mounted to a second circuit board.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

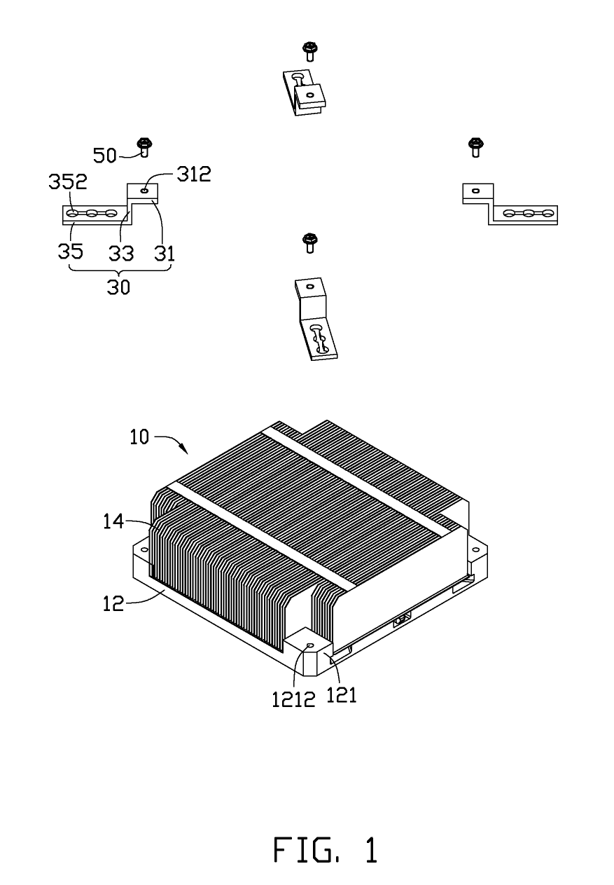

Referring to FIG. 1, an exemplary embodiment of a heat sink includes a main body 10, four fixing arms 30, and four connecting members 50.

The main body 10 is made of heat conductive material, such as copper or aluminum, or similar material, or an alloy. The main body 10 includes a substantially rectangular base 12, and a plurality of fins 14 extending up from the base 12. A boss 121 protrudes up from each of the four corners of the base 12. The boss 121 defines a coupling hole 1212.

Each of the fixing arms 30 includes a connection portion 31, an extension portion 33 extending down from an end of the connection portion 31, and a fixing portion 35 extending from a bottom end of the extension portion 33 opposite to the connection portion 31. The connection portion 31 defines a pivot hole 312. The fixing portion 35 defines a plurality of mounting holes 352, arranged uniformly in a row along the outward direction of the fixing portion 35.

In one embodiment, each of the connecting members 50 is a screw.

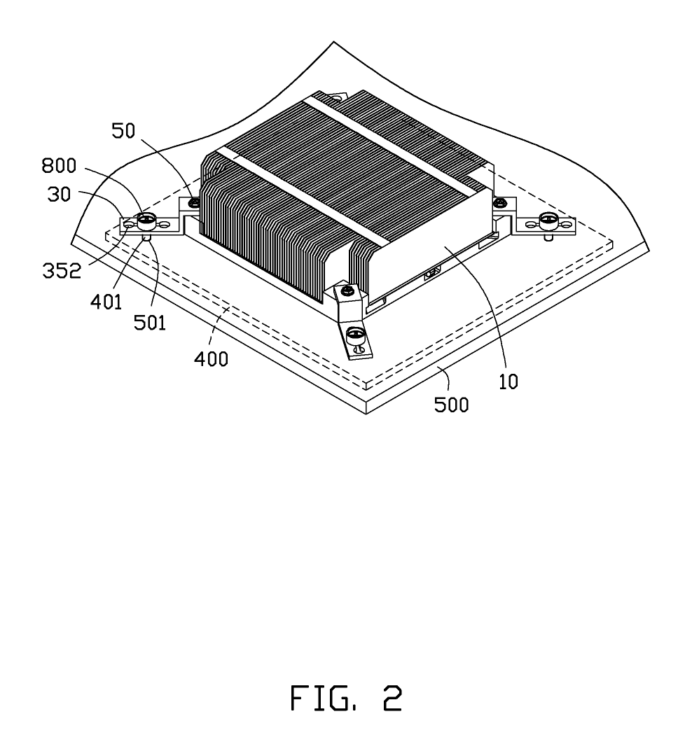

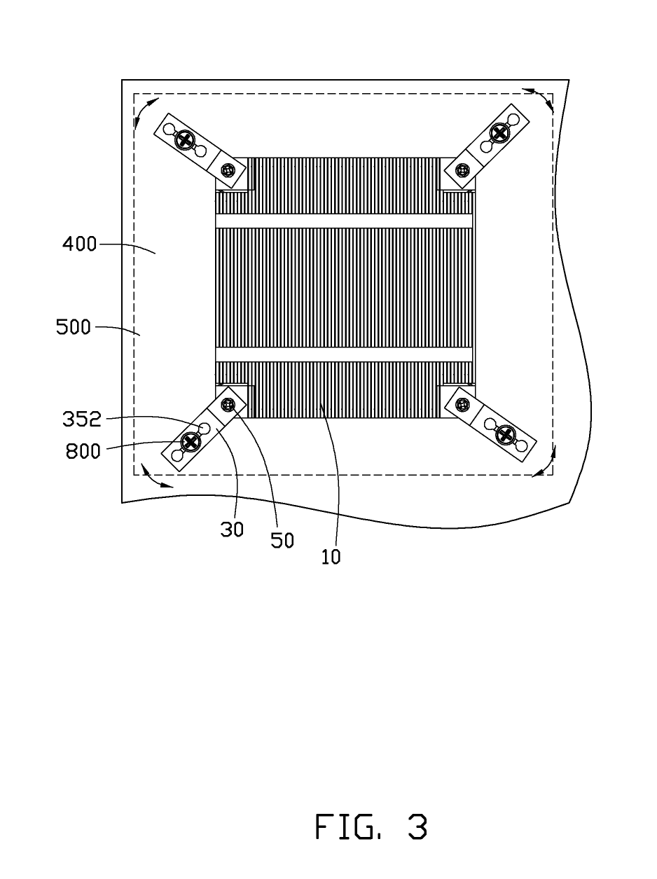

Referring to FIGS. 2 and 3, in assembly, the connections 31 rest on the tops of the corresponding bosses 121 to align the pivot holes 312 with the coupling holes 1212. The connecting members 50 extend through the pivot holes 312 and engage in the coupling holes 1212, to connect the fixing arms 30 to the main body 10. When one of the connecting members 50 is loosened, the fixing arm 30 it secures can be pivoted about the connecting member 50, allowing each of the mounting holes 352 to trace an individual circular path over the surface of a circuit board on which the main body 10 may be placed.

The heat sink is mounted to a first circuit board 500 with a fixing board 400 attached to a bottom surface of the circuit board 500. The first circuit board 500 defines a plurality of locating holes 501. A plurality of axially threaded locating columns 401 perpendicularly extends up from the fixing board 401, and extends through the locating holes 501. The main body 10 is placed on a top surface of the first circuit board 500, so as to align one of the mounting holes 352 of each of the fixing arms 30 with one of the locating columns 401. A screw 800 extends through one of the mounting holes 352 of each fixing arm 30 and engages in the locating column 401, to fix the heat sink to the first circuit board 500.

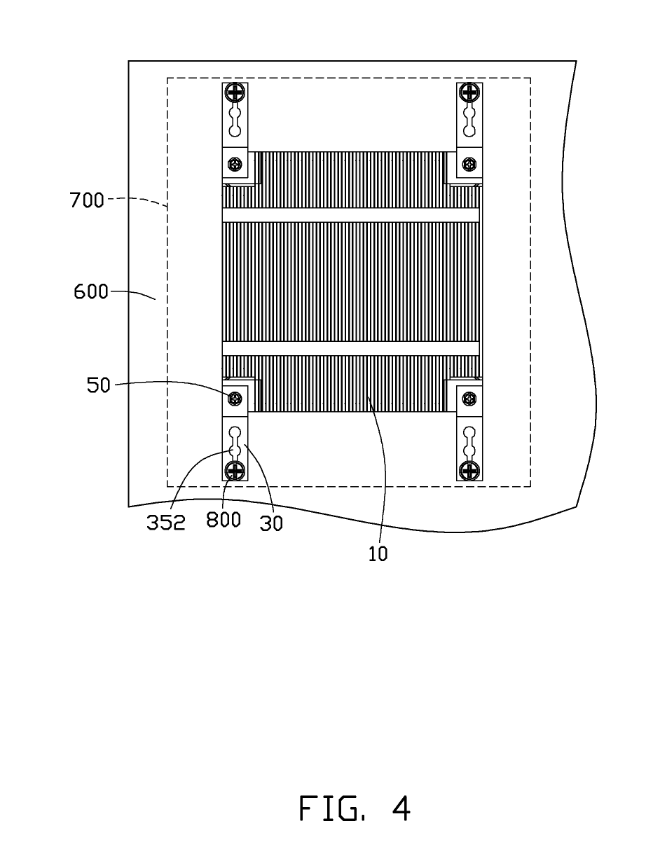

FIG. 4 shows a second circuit board 600 defining a plurality of locating holes (not shown) with a layout different from the locating holes 501 of the first circuit board 500. A second fixing board 700 includes a plurality of locating columns (not shown) extending through the locating holes of the second circuit board. The fixing arms 30 can pivot, thereby aligning each one of the mounting holes 352 of each of the fixing arms 30 with one of the locating columns. A screw 800 extends through the appropriate mounting hole 352 and engages in the mounting column In this way, the heat sink can be mounted to the second circuit board 600.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A heat sink to be mounted to a circuit board defining a plurality of locating holes, the heat sink comprising:
a main body to be attached on the circuit board; and
a plurality of fixing arms pivotally connected to the main body, each of the fixing arms defines at least one mounting hole;
wherein a location of each of the fixing arms is adjustable to align one of the at least one mounting hole of the fixing arm with a corresponding locating hole of the circuit board by pivoting the fixing arm.

2. The heat sink of claim 1, further comprising a plurality of connecting members, wherein the main body defines a plurality of coupling holes, each of the fixing arms defines a pivot hole aligning with a corresponding coupling hole of the main body, the connecting members extend through the pivot holes of the fixing arms, and are engaged in the corresponding coupling holes of the main body to allow the fixing arms pivoting about the corresponding connecting members.

3. The heat sink of claim 2, wherein the main body comprises a base forming a plurality of bosses on a top surface of the base, the coupling holes are correspondingly defined in the bosses, each of the fixing arms comprises a connection portion rested on a corresponding boss, an extension portion extending down from an end of the connection portion, and a fixing portion extending from a bottom end of the extension portion opposite to the main body, the at least one mounting holes is defined in the fixing portion, the pivot hole is defined in the connection portion.

4. The heat sink of claim 1, wherein the at least one mounting hole of each of the fixing arms comprises a plurality of mounting holes arranged in a row perpendicular to a tangential direction of a motion track of the connecting member.
